(19) United States
(12) Patent Application Publication
(10) Pub. No.: US 2020/0365646 A1
(43) Pub. Date: Nov. 19, 2020

(54) IMAGE SENSOR AND FABRICATION METHOD THEREOF

(71) Applicant: SZ DJI TECHNOLOGY CO., LTD., Shenzhen (CN)

(72) Inventor: Ze XU, Shenzhen (CN)

(21) Appl. No.: 16/988,034

(22) Filed: Aug. 7, 2020

Related U.S. Application Data
(63) Continuation of application No. PCT/CN2019/072719, filed on Jan. 22, 2019.

(51) Int. Cl. H01L 27/146

(52) U.S. Cl. CPC H01L 27/14685; H01L 27/14605; H01L 27/14627

(57) ABSTRACT

An image sensor includes a photo-sensing circuit region, a peripheral circuit region, and a light-blocking structure. The photo-sensing circuit region is formed in a semiconductor wafer and includes a plurality of photo-sensing devices. The peripheral circuit region is formed in the semiconductor wafer. The light-blocking structure is disposed between one or more of the plurality of photo-sensing devices and the peripheral circuit region. The light-blocking structure is configured to block at least a portion of light from reaching the one or more of the plurality of the photo-sensing devices, where the stray light comes from the peripheral circuit region. The light-blocking structure includes a material different from a material of the semiconductor wafer.

### CROSS-REFERENCE TO RELATED APPLICATION

This application is a continuation of International Application No. PCT/CN2019/072719, filed Jan. 22, 2019, the entire content of which is incorporated herein by reference.

### TECHNICAL FIELD

The present disclosure relates to the field of semiconductor design and fabrication and, more particularly, to an image sensor and a fabrication method for the image sensor.

### BACKGROUND

Image sensors, such as complementary metal-oxide-semiconductor (CMOS) image sensors, which can be fabricated on a standard semiconductor processing line, are widely used in consumer electronics, security monitoring, industrial automation, artificial intelligence, Internet of things, etc., for image data collection and organization, providing information for subsequent processing and application.

### SUMMARY

In accordance with the disclosure, there is provided an image sensor. The image sensor includes a photo-sensing circuit region, a peripheral circuit region, and a light-blocking structure. The photo-sensing circuit region is formed in a semiconductor wafer and includes a plurality of photo-sensing devices. The peripheral circuit region is formed in the semiconductor wafer. The light-blocking structure is disposed between one or more of the plurality of photo-sensing devices and the peripheral circuit region. The light-blocking structure is configured to block at least a portion of stray light from reaching the one or more of the plurality of the photo-sensing devices. The stray light comes from the peripheral circuit region. The light-blocking structure includes a material different from a material of the semiconductor wafer.

Also in accordance with the disclosure, there is provided a method of fabricating an image sensor. The method includes forming a device layer in a semiconductor wafer, where the device layer includes a photo-sensing circuit region and a peripheral circuit region, and the photo-sensing circuit region includes a plurality of photo-sensing devices. The method also includes forming a light-blocking structure in the semiconductor wafer between one or more of the plurality of photo-sensing devices and the peripheral circuit region. The light-blocking structure is configured to block at least a portion of stray light from reaching the one or more of the plurality of the photo-sensing devices. The stray light comes from the peripheral circuit region. The light-blocking structure includes a material different from a material of the semiconductor wafer.

### DESCRIPTION OF THE DRAWINGS

FIG. 1 schematically shows a plan view of an exemplary image sensor according to some embodiments of the present disclosure.

FIG. 2 schematically shows a cross-sectional view of the exemplary image sensor in FIG. 1.

FIG. 3 schematically shows a plan view of another exemplary image sensor according to some other embodiments of the present disclosure.

FIG. 4 schematically shows a cross-sectional view of the exemplary image sensor in FIG. 3.

FIG. 5A schematically shows an exemplary configuration of a light-blocking structure according to some embodiments of the present disclosure.

FIG. 5B schematically shows another exemplary configuration of a light-blocking structure according to some other embodiments of the present disclosure.

FIG. 6 schematically shows an exemplary image sensor including a light-reflecting structure according to some embodiments of the present disclosure.

FIG. 7 schematically shows another exemplary image sensor including a light-reflecting structure according to some other embodiments of the present disclosure.

FIG. 8 schematically shows an exemplary image sensor including a light-absorbing structure according to some embodiments of the present disclosure.

FIG. 9 schematically shows another exemplary image sensor according to some other embodiments of the present disclosure.

FIG. 10 is a flow chat of an exemplary method of fabricating an image sensor according to some embodiments of the present disclosure.

FIGS. 11A-11F illustrates an exemplary process implementing the method of fabricating an image sensor shown in FIG. 10.

FIGS. 12A-12F illustrates another exemplary process implementing the method of fabricating an image sensor shown in FIG. 10.

### REFERENCE NUMERALS FOR MAIN COMPONENTS

Image sensor—100
Device layer—10
Photo-sensing circuit region—110
Photo-sensing device—111
Peripheral circuit region—120
Light-blocking structure—130
Light-blocking sub-structure—131
Light-reflecting structure—132
Light-absorbing structure—133
Trench—134
Interconnect wire layer—20
Color-filter layer—30
Semiconductor wafer—40
Support substrate—50

### DETAILED DESCRIPTION

Technical solutions of the present disclosure will be described with reference to the drawings. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

Example embodiments will be described with reference to the accompanying drawings, in which the same numbers refer to the same or similar elements unless otherwise specified.

Unless otherwise defined, all the technical and scientific terms used herein have the same or similar meanings as generally understood by one of ordinary skill in the art. As described herein, the terms used in the specification of the present disclosure are intended to describe example embodiments, instead of limiting the present disclosure. The term “and/or” used herein includes any suitable combination of one or more related items listed.

An image sensor can include a photo-sensing circuit region and a peripheral circuit region formed on a semiconductor wafer. The peripheral circuit can be formed around the photo-sensing circuit region for, e.g., driving the components or devices in the photo-sensing circuit region. The photo-sensing circuit region can be configured to sense light and generate digital image data to form an image. Sometimes, unwanted light may enter the photo-sensing circuit region, e.g., from the peripheral circuit region. Such light, also referred to as stray light, may be generated in the peripheral circuit region or may be generated somewhere else but passing through the peripheral circuit region to enter the photo-sensing circuit region. For example, the image sensor can include various portions made of semiconductor materials. When the image sensor is in operation, recombination of charge carriers (e.g., electrons and holes) of the semiconductor materials in the peripheral circuit region can generate photons, forming stray light. The stray light may enter the photo-sensing region, e.g., through the semiconductor wafer of the image sensor, and be absorbed by the photo-sensing circuit, forming interference signals, which can be a source noise. As such, the signal-to-noise ratio of the image sensor may be reduced, and a quality of the images acquired by the image sensor may be decreased.

The present disclosure provides an image sensor including a light-blocking structure. The image sensor may be a complementary metal-oxide-semiconductor (CMOS) image sensor, an N-type metal-oxide-semiconductor (NMOS) image sensor, or a P-type metal-oxide-semiconductor (PMOS) image sensor, etc. The image sensor may be a backside-illuminated (BSI) image sensor or a frontside-illuminated (FSI) image sensor. For example, the image sensor can be a BSI CMOS image sensor. The image sensor can sense incident light and generate digital image data through light-to-voltage conversion.

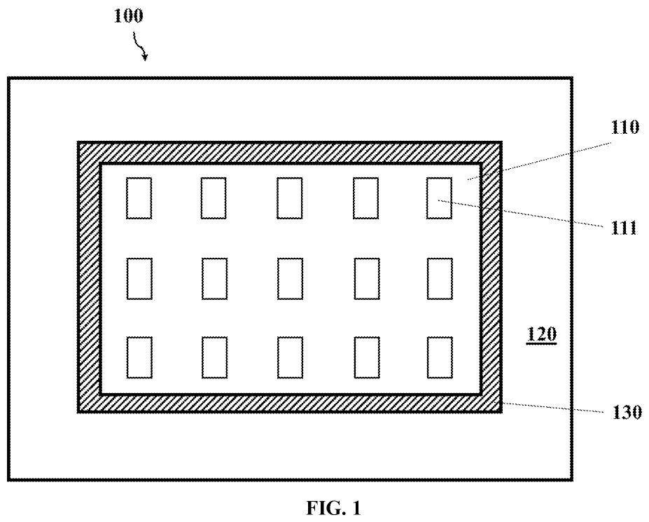

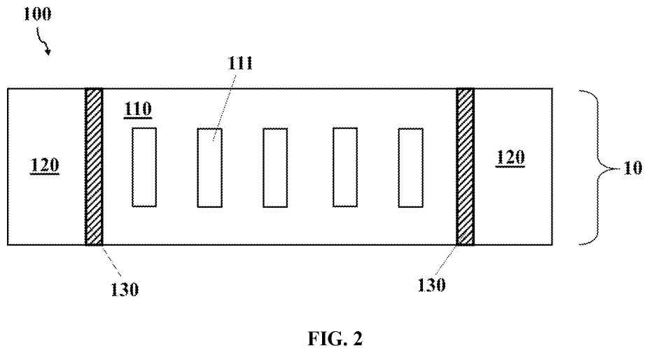

FIG. 1 and FIG. 2 schematically show an exemplary image sensor 100 according to some embodiments of the present disclosure. FIG. 1 is a plan view of the image sensor 100 and FIG. 2 is a cross-sectional view of the image sensor 100. The image sensor 100 can be formed in a semiconductor wafer and includes a device layer 10 formed in the semiconductor wafer. The device layer 10 includes a photo-sensing circuit region 110, a peripheral circuit region 120, and a light-blocking structure 130. The photo-sensing circuit region 110 is configured to sense incident light to generate digital image data through a light-to-voltage conversion. The peripheral circuit region 130 is configured to acquire the digital image data generated by the photo-sensing circuit region 110 and/or control the operation of the photo-sensing circuit region 110. As shown in FIGS. 1 and 2, the photo-sensing circuit region 110 includes a plurality of photo-sensing devices 111. In some embodiments, each of the plurality of photo-sensing devices 111 may correspond to one or more pixels of the image acquired by the image sensor. In some embodiments, two or more of the plurality of photo-sensing devices 111 may correspond to one pixel of the image acquired by the image sensor 100, i.e., one photo-sensing device 111 may correspond to a sub-pixel.

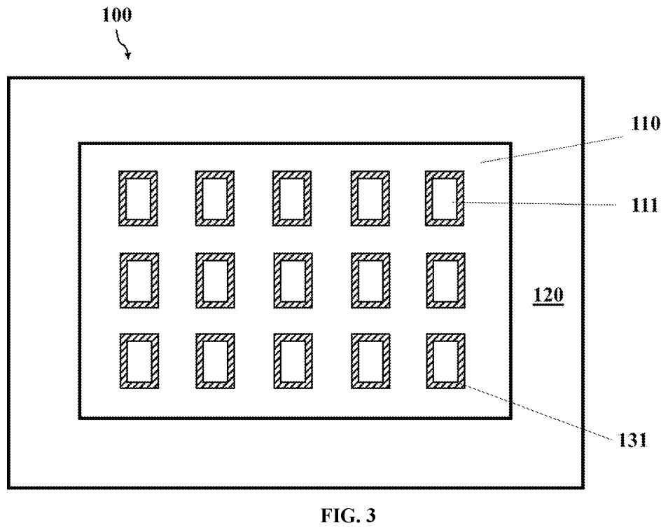

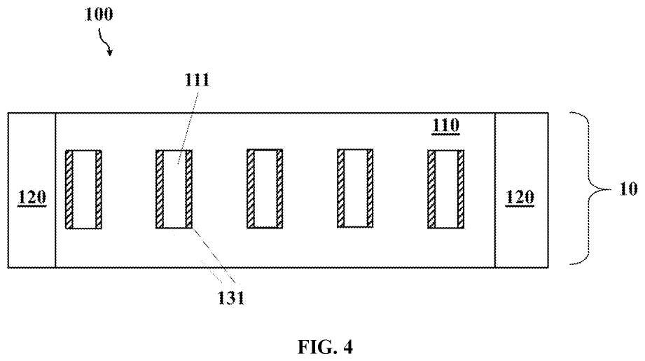

In some embodiments, the light-blocking structure 130 is located between one or more of the photo-sensing devices 111 and the peripheral circuit region 120. For example, as shown in FIGS. 1 and 2, the light-blocking structure 130 can surround the photo-sensing circuit region 110 for blocking the stray light from reaching the photo-sensing circuit region 110. In some other embodiments, the light-blocking structure 130 may include a plurality of light-blocking sub-structures, and each of the plurality of the light-blocking sub-structures surrounds one or more of the photo-sensing devices. FIGS. 3 and 4 schematically show another exemplary image sensor 100 according to some embodiments of the present disclosure. FIG. 3 is a plan view of the image sensor 100 and FIG. 4 is a cross-sectional view of the image sensor 100. In the example shown in FIGS. 3 and 4, the light-blocking structure 130 includes a plurality of light-blocking sub-structures 131, and each of the plurality of light-blocking sub-structures 131 surrounds one photo-sensing device 111. The light-blocking sub-structures 131 can block at least a portion of the stray light from reaching the photo-sensing devices 111. In some embodiments, each of at least one of the plurality of light-blocking sub-structures 131 can surround two or more photo-sensing devices 111. Each of the light-blocking sub-structures 131 can block at least a portion of the stray light from reaching the photo-sensing device(s) 111 surrounded by that light-blocking sub-structure 131.

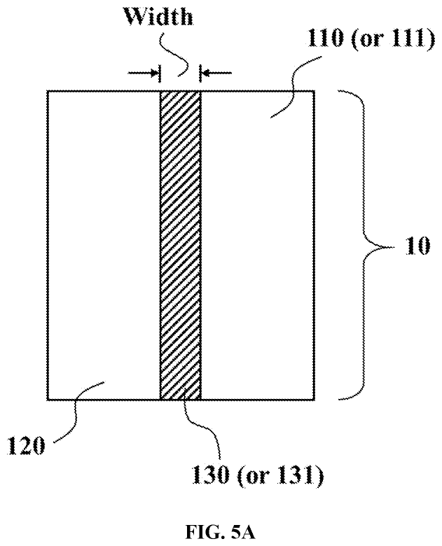

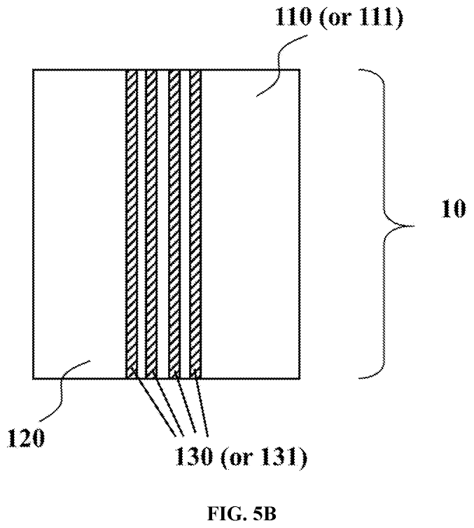

FIGS. 5A and 5B are enlarged views of a portion of the light-blocking structure 130 or a portion of a light-blocking sub-structure 131 consistent with the disclosure. FIGS. 5A and 5B show two different exemplary configurations of the light-blocking structure 130/light-blocking sub-structure 131, respectively, according to some embodiments of the present disclosure. In some embodiments, as shown in FIG. 5A, the light-blocking structure 130/light-blocking sub-structure 131 includes a continuous, integral structure. In some other embodiments, the light-blocking structure 130/light-blocking sub-structure 131 may include a plurality of light-blocking elements. A number of the light-blocking elements may be 1, 2, 3, . . . , or 10, etc. In some embodiments, the plurality of light-blocking elements can be arranged in parallel. In some other embodiments, two or more of the plurality of light-blocking elements can be arranged not parallel to each other. For example, as shown in FIG. 5B, the light-blocking structure 130/light-blocking sub-structure 131 includes four light-blocking elements arranged in parallel. Two adjacent ones of the plurality of light-blocking elements can be spaced apart from each other by a suitable distance, e.g., a distance in a range from about 1 μm to about 20 μm.

A width (as indicated in, e.g., FIG. 5A) and a shape of the light-blocking structure 130/light-blocking sub-structure 131 can be configured taking into consideration, e.g., light-blocking effect, the ratio of an effective area (e.g., a sum of an area of the peripheral circuit region 120 and an area of the photo-sensing circuit region 110) over a total area of the image sensor 100, the technical limit of fabrication, and/or other factors. For example, the width of the light-blocking structure 130/light-blocking sub-structure 131 may be a value in a range, e.g., from about 0.1 μm to about 2 μm, and a cross section of the light-blocking structure 130/light-blocking sub-structure 131 can have a rectangular shape or a trapezoidal shape, etc.

In some embodiments, the light-blocking structure 130/light-blocking sub-structure 131 may be directly in contact with the photo-sensing circuit region 110/photo-sensing device 111. In some other embodiments, the light-blocking structure 130/light-blocking sub-structure 131 may be spaced from the photo-sensing circuit region 110/photo-sensing device 111. For example, a distance between the photo-sensing circuit region 110 and the light-blocking structure 130 can be a value in a range, e.g., from 5 μm to about 100 μm.

A material of the light-blocking structure 130 can be different from a material of the semiconductor wafer, and the light-blocking structure can have different physical and/or chemical properties than the semiconductor wafer.

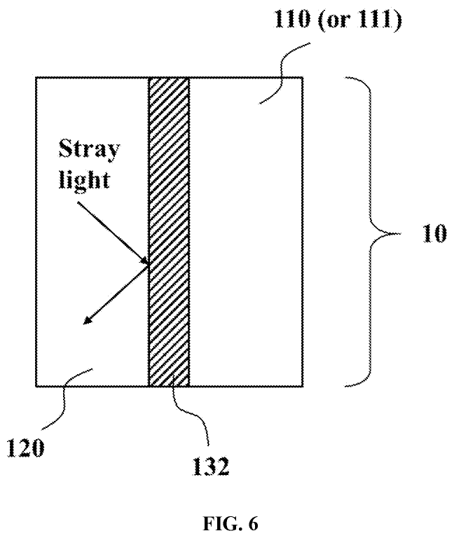

In some embodiments, the light-blocking structure 130 can be a light-reflecting structure 130. FIG. 6 is an enlarged view of a portion of an exemplary image sensor 100 including a light-reflecting structure 132 as the light-blocking structure 130 consistent with the disclosure. The light-reflecting structure 132 can, as a whole, surround the entire photo-sensing circuit region 110, or include a plurality of light-reflecting sub-structures each surrounding one or more photo-sensing devices 111 of the photo-sensing circuit region 110. In some embodiments, a refractive index of the light-reflecting structure 132 can be lower than a refractive index of the peripheral circuit region 120, such that at least a portion of the stray light can be reflected at an interface between the peripheral circuit region 120 and the light-reflecting structure 132, thereby blocking the at least a portion of the stray light from reaching the photo-sensing circuit region 110 or the photo-sensing devices 111 in the photo-sensing circuit region 110. A material with suitable physical and/or chemical properties (e.g., having a lower refractive index than the semiconductor wafer) can be used to form the light-reflecting structure 132. For example, the light-reflecting structure 132 can be made of one or more of silicon dioxide, silicon nitride, tungsten, hafnium oxide, or carbon, etc.

In the embodiments described above, the light-reflecting structure 132 is configured to reflect the stray light by being made of a material having a lower refractive index than the semiconductor wafer. In these embodiments, the reflection of the stray light can be realized by the total reflection at the interface between the light-reflecting structure 132 and the material surrounding the light-reflecting structure 132, such as the semiconductor wafer. Therefore, a portion of the stray light incident on the interface at certain angles may not be reflected but still pass through the light-reflecting structure 132. In some other embodiments, the light-reflecting structure 132 can be made of a light-reflecting material that is by itself capable of reflecting light. In these embodiments, the light-reflecting structure 132 can reflect the stray light no matter what the incident angle of the stray light at the interface is. In this case, specular light refection may occur when the stray light incident onto the interface.

In some embodiments, the light-reflecting structure 130 may include a plurality of layers. The plurality of layers may be made of a same material or different materials. For example, each of the plurality of players can be made of silicon dioxide, silicon nitride, tungsten, hafnium oxide, or carbon, etc. In some embodiments, to enhance the heat dissipation capability of the light-reflecting structure 132 (and hence the heat dissipation capability of the image sensor 100), light-reflecting structure 132 may have a good heat dissipation capability and a refractive index lower than that of the semiconductor wafer. For example, the light-reflecting structure 132 may be made of a material with both a good heat dissipation capability and a refractive index lower than that of the semiconductor wafer. For another example, the light-reflecting structure 132 may be made of one or more materials with a good heat dissipation capability and one or more materials with a refractive index lower than that of the semiconductor wafer. For the light-reflecting structure 132 including a plurality of layers, one or more layers of the plurality of layers may have good heat dissipation capability, and the other layers of the plurality of layers may have a refractive index lower than that of the semiconductor wafer.

A shape of the light-reflecting structure 132 can be selected taking into consideration, e.g., the light-blocking effect, the ratio of an effective area over the total area of the image sensor 100, the technical limit of fabrication, and/or other factors. In the example shown in FIG. 6, a cross section of the light-reflecting structure 132 has a rectangular shape. FIG. 6 is a cross-sectional view showing another exemplary light-reflecting structure 132 having a trapezoidal shape. The angles of the trapezoidal shape can be selected according to, e.g., a ratio of the refractive index of the light-reflecting structure 132 to the refractive index of the peripheral circuit region 120. For example, the trapezoidal shape may have at least one angle α between 80 degree and 90 degree.

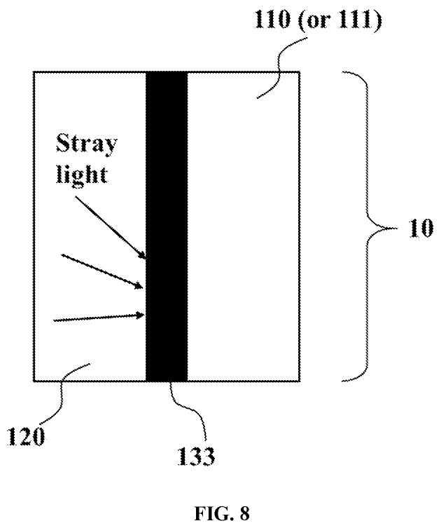

In some embodiments, the light-blocking structure 130 may be a light-absorbing structure 133 including a light-absorbing material. FIG. 8 is an enlarged view of a portion of another exemplary image sensor 100 including a light-absorbing structure 133 as the light-blocking structure 130 consistent with the disclosure. Similar to the light-reflecting structure 132, the light-absorbing structure 133 can, as a whole, surround the entire photo-sensing circuit region 110, or include a plurality of light-absorbing sub-structures each surrounding one or more photo-sensing devices 111 of the photo-sensing circuit region 110. In some embodiments, a light absorption coefficient of the light-absorbing structure 133 can be larger than a light absorption coefficient of the semiconductor wafer, such that the light-absorbing structure 133 can absorb at least a portion of the stray light incident on the light-absorbing structure 133, thereby blocking the at least a portion of the stray light from reaching the photo-sensing circuit region 110 or the photo-sensing devices 111 in the photo-sensing circuit region 110. A material with suitable physical and/or chemical properties (e.g., having a higher light absorption capability than the semiconductor wafer) can be used to form the light-absorbing structure 133. In some embodiments, the light-absorbing structure 133 may have a darker color than the semiconductor wafer. For example, the light-absorbing structure can have a black color.

In some embodiments, the light-absorbing structure 133 can include a plurality of layers. The plurality of layers may be made of a same material or different materials. The stray light absorbed by the light-absorbing structure can generate heat. Thus, to enhance the heat dissipation capability of the light-absorbing structure 133 (and hence the heat dissipation capability of the image sensor 100), the light-absorbing structure 133 may have a good heat dissipation capability and a light absorption capability higher than that of the semiconductor wafer. For example, the light-absorbing structure 133 may be made of a material with both a good heat dissipation capability and a light absorption capability higher than that of the semiconductor wafer. For another example, the light-absorbing structure 133 may be made of one or more materials with a good heat dissipation capability and one or more materials with a light absorption capability higher than that of the semiconductor wafer. For the light-absorbing structure 133 including a plurality of layers, one or more layers of the plurality of layers may have good heat dissipation capability, and the other layers of the plurality of layers may have a light absorption capability higher than that of the semiconductor wafer.

In some embodiments, the image sensor may include other components besides the device layer 10. FIG. 9 shows an exemplary image sensor 100 (e.g., a BSI CMOS image sensor) according to some embodiments of the present disclosure. The image sensor 100 includes the device layer 10, an interconnect wire layer 20, and a color-filter layer 30. The photo-sensing circuit region 110, the peripheral circuit region 120, and the light-blocking structure 130 are in the device layer 10 of the image sensor 100. The interconnect wire layer 20 is located at one side (e.g., a first side) of the device layer 10 for coupling two or more components in an integrated chip of the image sensor 100. The interconnect wire layer 20 may include multiple metal interconnect layers and intermetal dielectric layers. The color-filter layer 30 includes a plurality of color filters and is located at another side (e.g., a second side) of the device layer for filtering incident light to obtain different color components of the incident light. For example, a red component, a green component, and a blue component of the incident light can be obtained by filtering the incident light by the color filter layer 30.

In some embodiments, the image sensor may also include a micro-lens array arranged, e.g., on a side of the color filter layer opposite to the side facing the device layer. The micro-lens array can include a plurality of micro lenses for focusing light onto the photo-sensing devices 111. Each of the micro lenses may have a flat surface and/or an aspherical surface. The focused incident light can be filtered by the color filter layer 30 and sensed by the photo-sensing circuit region 110 of the device layer 10 to generate the digital image data.

By configuring the image sensor 100 with the light-blocking structure 130, a part of or all of the stray light can be prevented from travelling from the peripheral circuit region 120 into the photo-sensing circuit region 110. As such, the interference signal (e.g., noise) caused by the stray light can be reduced, and hence the signal-to-noise ratio of the image sensor 100 and the maximum amplification applied to the output signal can both be increased. Therefore, the quality of the image acquired by the image sensor 100 can be improved.

In addition, compared to the existing technologies, the light-blocking structure 130 can have a much smaller cross-sectional width than a dummy region used in the existing technologies. As such, the image sensor 100 provided by the present disclosure can have a relative higher ratio of effective area over the total area of the image sensor 100. Thus, the image sensor provided by the present disclosure can be more compact, and the cost of materials for fabricating the image sensor can be lowered.

Another aspect of the present disclosure provides a method of fabricating an image sensor including a light-blocking structure. The image sensor may be a complementary metal-oxide-semiconductor (CMOS) image sensor, an N-type metal-oxide-semiconductor (NMOS) image sensor, or a P-type metal-oxide-semiconductor (PMOS) image sensor, etc. The image sensor may be a backside-illuminated (BSI) image sensor or a frontside-illuminated (FSI) image sensor. For example, the image sensor can be a BSI CMOS image sensor. The image sensor can sense incident light and generate digital image data through light-to-voltage conversion.

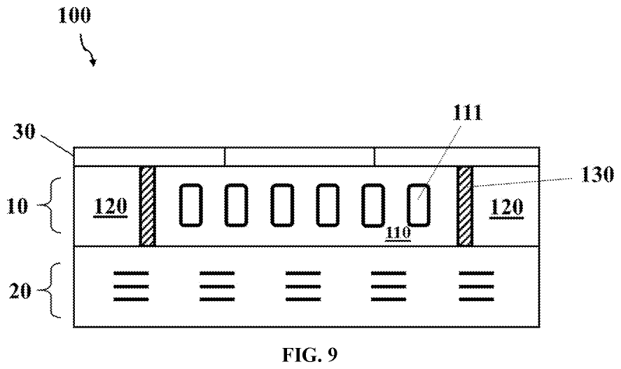

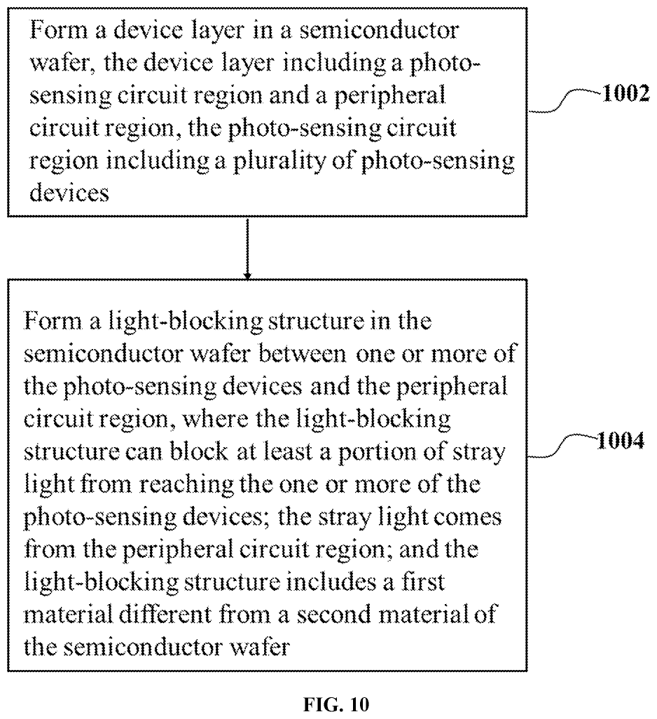

FIG. 10 is a flow chat of an exemplary method of fabricating an image sensor. As shown in FIG. 10, the method includes the following processes.

At 1002, a device layer is formed in a semiconductor wafer. The device layer includes a photo-sensing circuit region and a peripheral circuit region. The photo-sensing circuit region includes a plurality of photo-sensing devices.

At 1004, a light-blocking structure is formed in the semiconductor wafer between one or more photo-sensing devices and the peripheral circuit region. The light-blocking structure can block at least a portion of stray light from reaching the one or more of the photo-sensing devices, where the stray light comes from the peripheral circuit region. The material of the light-blocking structure is different from the material of the semiconductor wafer.

In some embodiments, the image sensor may include other components besides the device layer. For example, the image sensor can be a BSI CMOS image sensor and includes the device layer, an interconnect wire layer, and a color-filter layer. The photo-sensing circuit region, the peripheral circuit region, and the light-blocking structure are in the device layer of the image sensor. The interconnect wire layer is located at one side (e.g., a first side) of the device layer for coupling two or more components in an integrated chip of the image sensor. The interconnect layer may include multiple metal interconnect layers and intermetal dielectric layers. The color-filter layer includes a plurality of color filters and is located at another side (e.g., a second side) of the device layer for filtering incident light to obtain different color components of the incident light. For example, a red component, a green component, and a blue component of the incident light can be obtained by filtering the incident light by the color filter layer.

In some embodiments, the image sensor may also include a micro-lens array arranged, e.g., on a side of the color filter layer opposite to the side facing the device layer. The micro-lens array can include a plurality of micro lenses for focusing light onto the photo-sensing devices. Each of the micro lenses may have a flat surface and/or an aspherical surface. The focused incident light can be filtered by the color filter layer and sensed by the photo-sensing circuit region of the device layer to generate digital image data.

The method of fabricating the image sensor consistent with the present disclosure can be implemented in different processes.

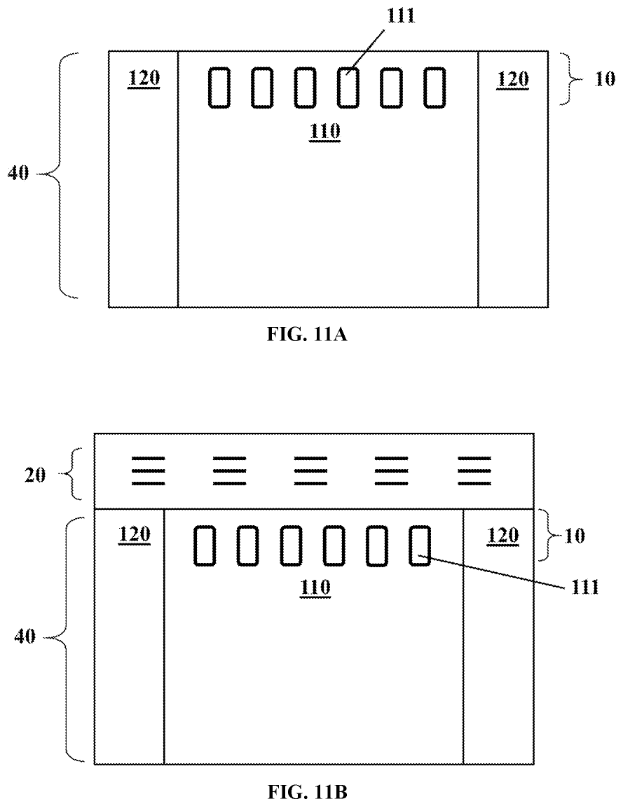

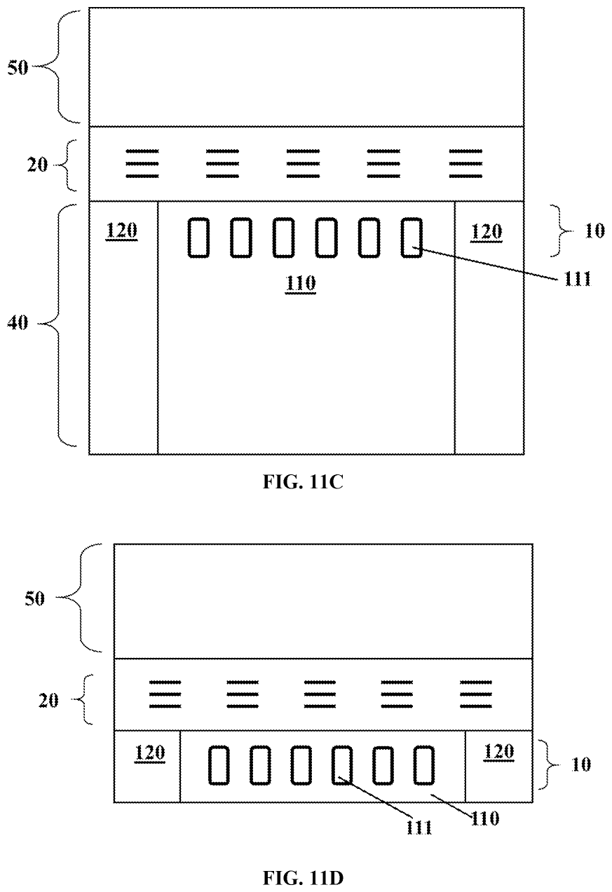

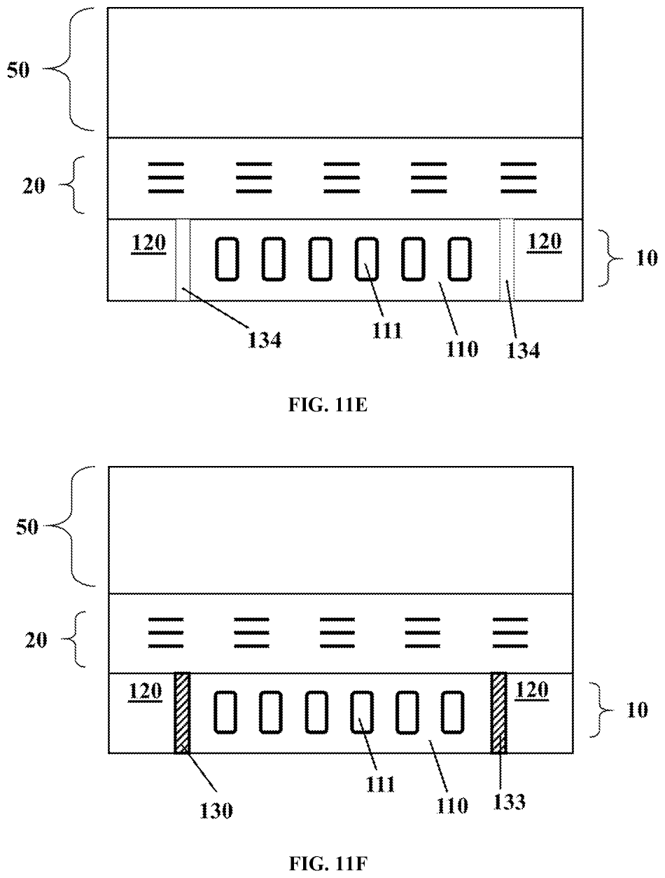

FIGS. 11A-11F illustrate an exemplary process implementing the method of fabricating an image sensor consistent with the present disclosure. As shown in FIG. 11A, a device layer 10 is formed at a first side (e.g., an upper side shown in FIG. 11A), of a semiconductor wafer 40. The device layer 10 includes a peripheral circuit region 120 and a photo-sensing circuit region 110. The photo-sensing circuit region 110 is configured to sense incident light to generate digital image data through a light-to-voltage conversion. The peripheral circuit region 120 is configured to acquire the digital image data generated by the photo-sensing circuit region 110 and/or control the operation of the photo-sensing circuit region 110. The photo-sensing circuit region 110 includes a plurality of photo-sensing devices 111. In some embodiments, each of the plurality of photo-sensing devices 111 may correspond to one or more pixels of the image acquired by the image sensor. In some embodiments, two or more of the plurality of photo-sensing devices 111 may correspond to one pixel of the image acquired by the image sensor, i.e., one photo-sensing device 111 may correspond to a sub-pixel.

Referring to FIGS. 11B and 11C, an interconnect wire layer 20 is then formed on the device layer 10, followed by bonding a support substrate 50 to the interconnect wire layer 20. The support substrate 50 and the semiconductor wafer 40 are located at opposite sides of the interconnect wire layer 20. The interconnect layer 20 can couple two or more components in an integrated chip of the image sensor and may include multiple metal interconnect layers and intermetal dielectric layers.

As shown in FIG. 11D, the semiconductor wafer 40 is thinned from a second side (e.g., a lower side shown in FIG. 11D) of the semiconductor wafer 40. The semiconductor wafer 40 can be thinned to a thickness in a range, e.g., from about 2 μm to about 6 The thickness of the semiconductor wafer 40 after the thinning process may equal to a thickness of the device layer 10. For example, the thickness of the device layer may be in a range, e.g., from about 2 μm to about 6 μm.

The semiconductor wafer 40 is then etched from the second side to form one or more trenches 134 between the one or more of the photo-sensing devices 111 and the peripheral circuit region 120 (shown in FIG. 11E). The one or more trenches 134 can be filled with a material that is different from the material of the semiconductor wafer 40, to form the light-blocking structure 130 (shown in FIG. 11F). As such, the image sensor including a light-blocking structure 130 can be obtained. Sequence of one or more processes illustrated in FIGS. 11A-11F can be altered and is not limited by the present disclosure. Some processes illustrated in FIGS. 11A-11F can be merged (e.g., executed simultaneously) or omitted. For the purpose of simplification, the light-blocking structure 130 in FIGS. 11A-11F surrounds the photo-sensing-circuit region 110. The processes illustrated in FIGS. 11A-11F can also be used to fabricate the light-blocking structure 130 with another configuration, e.g., the light-blocking structure 130 including a plurality of light-blocking sub-structures, and each of the plurality of light-blocking sub-structures surrounding one or more photo-sensing devices 111.

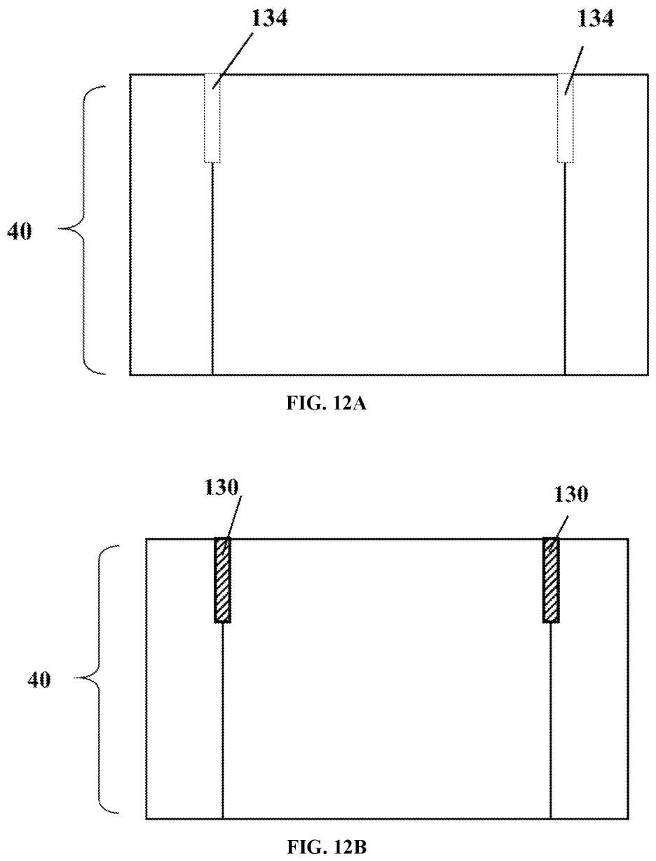

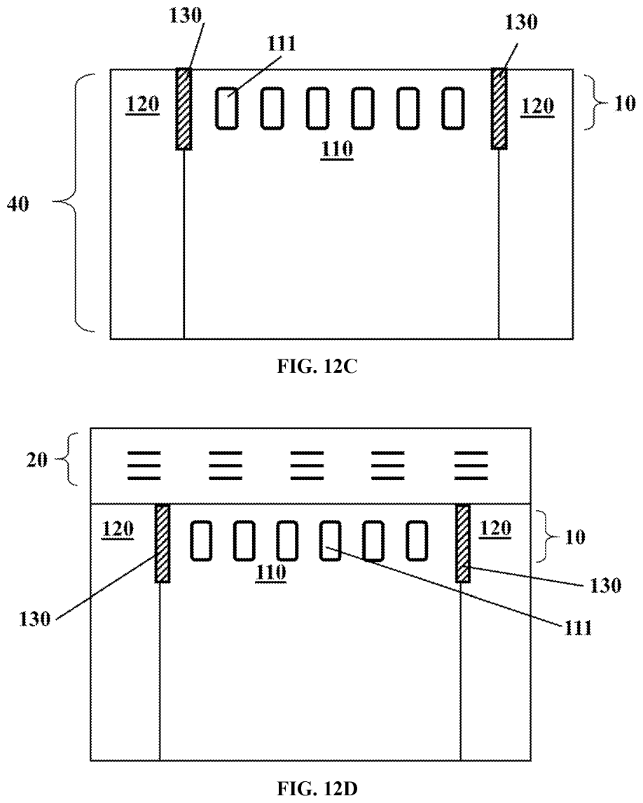

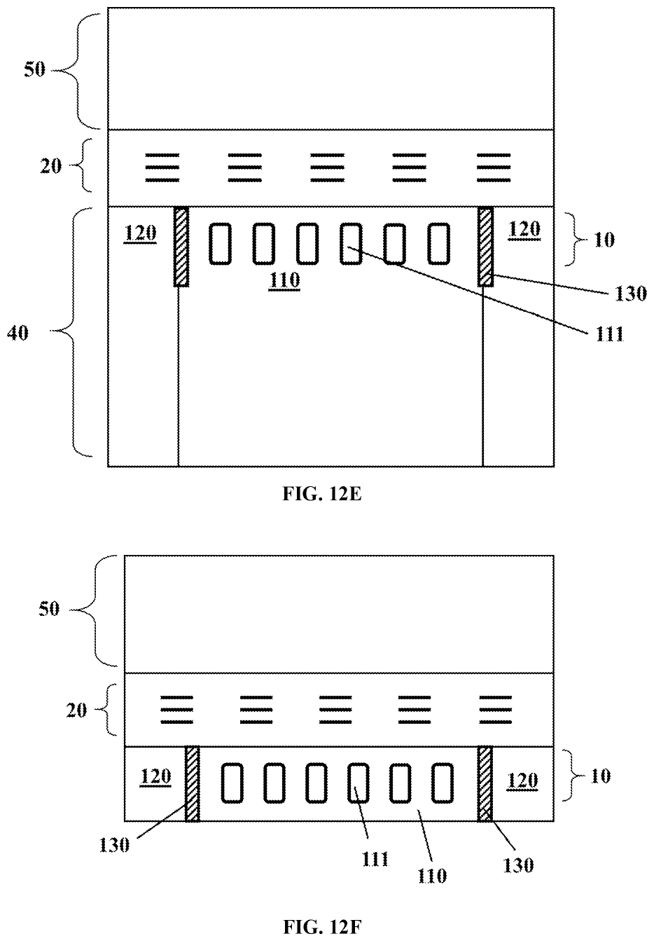

FIGS. 12A-12F illustrates another exemplary process implementing the method of fabricating an image sensor consistent with the present disclosure. As shown in FIGS. 12A and 12B, one or more trenches 134 are formed by etching a first side (e.g., an upper side shown in FIG. 12A) of a semiconductor wafer 40, followed by forming the light-blocking structure 130 by filling the trenches 134 with a material different from the material of the semiconductor wafer 40.

As shown in FIG. 12C, a device layer 10 is formed at the first side of the semiconductor wafer 40. The device layer 10 includes a peripheral circuit region 120 and a photo-sensing circuit region 110. The photo-sensing circuit region 110 includes a plurality of photo-sensing devices 111. The photo-sensing circuit region 110 is configured to sense incident light to generate digital image data through a light-to-voltage conversion. The peripheral circuit region 120 is configured to acquire the digital image data generated by the photo-sensing circuit region 110 and/or control the operation of the photo-sensing circuit region 110. The photo-sensing circuit region 110 includes a plurality of photo-sensing devices 111. In some embodiments, each of the plurality of photo-sensing devices 111 may correspond to one or more pixels of the image acquired by the image sensor. In some embodiments, two or more of the plurality of photo-sensing devices 111 may correspond to one pixel of the image acquired by the image sensor, i.e., one photo-sensing device 111 may correspond to a sub-pixel.

Referring to FIGS. 12D and 12E, an interconnect wire layer 20 is formed on the device layer 10. A support substrate 50 is then bonded to the interconnect wire layer 20. The support substrate 50 and the semiconductor wafer 40 are located at opposite sides of the interconnect wire layer 20. The interconnect layer 20 can couple two or more components in an integrated chip of the image sensor and may include multiple metal interconnect layers and intermetal dielectric layers.

As shown in FIG. 12F, the semiconductor wafer 40 is thinned from a second side (e.g., a lower side) of the semiconductor wafer. As such, the image sensor including a light-blocking structure 130 can be obtained. The semiconductor wafer 40 can be thinned to a thickness in a range, e.g., from about 2 μm to about 6 μm. The thickness of the semiconductor wafer 40 after the thinning process may equal to a thickness of the device layer 10. For example, the thickness of the device layer may be in a range, e.g., from about 2 μm to about 6 μm. Sequence of one or more processes illustrated in FIGS. 12A-12F can be altered and is not limited by the present disclosure. Some processes illustrated in FIGS. 12A-12F can be merged (e.g., executed simultaneously) or omitted. For the purpose of simplification, the light-blocking structure 130 in FIGS. 12A-12F surrounds the photo-sensing-circuit region 110. The processes illustrated in FIGS. 12A-12F can also be used to fabricate the light-blocking structure 130 with another configuration, e.g., the light-blocking structure 130 including a plurality of light-blocking sub-structures, and each of the plurality of light-blocking sub-structures surrounding one or more photo-sensing devices 111.

In some embodiments, the light-blocking structure is formed between one or more of the photo-sensing devices and the peripheral circuit region. For example, as shown in FIGS. 1 and 2, the light-blocking structure can surround the photo-sensing circuit region for blocking at least a portion of the stray light from reaching the photo-sensing circuit region. In some other embodiments, the light-blocking structure may include a plurality of light-blocking sub-structures, and each of the plurality of the light-blocking sub-structures surrounds one or more of the photo-sensing devices. For example, as shown in FIGS. 3 and 4, the light-blocking structure includes a plurality of light-blocking sub-structures, and each of the plurality of the light-blocking sub-structures can surround one photo-sensing device. The light-blocking sub-structures can block at least a portion of the stray light from reaching the photo-sensing devices.

In some embodiments, a light-blocking structure/light-blocking sub-structure includes a continuous integral structure. In some other embodiments, the light-blocking structure/light-blocking sub-structure may include a plurality of light-blocking elements. A number of the light-blocking elements may be 1, 2, 3, . . . , or 10, etc. In some embodiments, the plurality of light-blocking elements can be arranged in parallel. Two adjacent ones of the plurality of light-blocking elements can be spaced apart from each other by a suitable distance, e.g., a distance ranged from about 1 μm to about 20 In some other embodiments, two or more of the plurality of light-blocking elements can be arranged not parallel to each other.

A width (as indicated in, e.g., FIG. 5A) and a shape of the light-blocking structure/light-blocking sub-structure can be configured taking into consideration, e.g., light-blocking effect, the ratio of an effective area versus the total area of the image sensor 100, the technical limit of fabrication, and/or other factors. For example, the width of the light-blocking structure/light-blocking sub-structure may be a value in a range from about 0.1 μm to about 2 and a cross section of the light-blocking structure/light-blocking sub-structure can have a rectangular shape or a trapezoidal shape, etc.

In some embodiments, the light-blocking structure may be formed in direct contact with the photo-sensing circuit region. In some other embodiments, the light-blocking structure may be spaced from the photo-sensing circuit region. For example, a distance between the photo-sensing circuit region and the light-blocking structure can be a value in a range from 5 μm to about 100 μm.

A material of the light-blocking structure can be different from a material of the semiconductor wafer, and the light-blocking structure can have different physical and/or chemical properties than the semiconductor wafer.

In some embodiments, the light-blocking structure can be a light-reflecting structure. The light-reflecting structure can, as a whole, surround the entire photo-sensing circuit region, or include a plurality of light-reflecting sub-structures each surrounding one or more photo-sensing devices of the photo-sensing circuit region. In some embodiments, a refractive index of the light-reflecting structure can be lower than a refractive index of the peripheral circuit region, such that the light-reflecting structure can reflect at least a portion of the stray light at an interface between the peripheral circuit region and the light-reflecting structure, thereby blocking the at least a portion of the stray light from reaching the photo-sensing circuit region or the photo-sensing devices in the photo-sensing circuit region. A material with suitable physical and/or chemical properties (e.g., having a lower refractive index than the semiconductor wafer) can be used to form the light-reflecting structure. For example, the light-reflecting structure can be made of one of silicon dioxide, silicon nitride, tungsten, hafnium oxide, or carbon, etc.

In the embodiments described above, the light-reflecting structure is configured to reflect the stray light by being made of a material having a lower refractive index than the semiconductor wafer. In these embodiments, the reflection of the stray light can be realized by the total reflection at the interface between the light-reflecting structure and the material surrounding the light-reflecting structure, such as the semiconductor wafer. Therefore, a portion of the stray light incident on the interface at certain angles may not be reflected but still pass through the light-reflecting structure. In some other embodiments, the light-reflecting structure can be made of a light-reflecting material that is by itself capable of reflecting light. In these embodiments, the light-reflecting structure can reflect the stray light no matter what the incident angle of the stray light at the interface is. In this case, specular light refection may occur when the stray light incident onto the interface.

In some embodiments, the light-reflecting structure may include a plurality of layers. The plurality of layers may be made of a same material or different materials. For example, each of the plurality of players can be made of silicon dioxide, silicon nitride, tungsten, hafnium oxide, or carbon, etc. In some embodiments, to enhance the heat dissipation capability of the light-reflecting structure (and hence the heat dissipation capability of the image sensor), light-reflecting structure may have a good heat dissipation capability and a refractive index lower than that of the semiconductor wafer. For example, the light-reflecting structure may be made of a material with both a good heat dissipation capability and a refractive index lower than that of the semiconductor wafer. For another example, the light-reflecting structure may be made of one or more materials with a good heat dissipation capability and one or more materials with a refractive index lower than that of the semiconductor wafer. For the light-reflecting structure including a plurality of layers, one or more layers of the plurality of layers may have good heat dissipation capability, and the other layers of the plurality of layers may have a refractive index lower than that of the semiconductor wafer

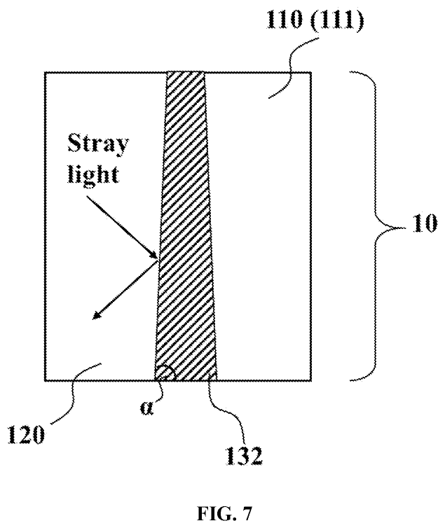

A shape of the light-reflecting structure can be selected taking into consideration, e.g., the light-blocking effect, the ratio of the effective area over the total area of the image sensor 100, the technical limit of fabrication, and/or other factors. In the example shown in FIG. 6, a cross section of the light-reflecting structure can have a rectangular shape or a trapezoidal shape, etc. In another example shown in FIG. 7, the light-blocking structure can have a trapezoidal shape. The angles of the trapezoidal shape can be selected according to, e.g., a ratio of the refractive index of the light-blocking structure to the refractive index of the peripheral circuit region. For example, referring to FIG. 6, the trapezoidal shape may have at least one angle α between 80 degree and 90 degree.

In some embodiments, the light-blocking structure may be a light-absorbing structure including a light-absorbing material. Similar to the light-reflecting structure, the light-absorbing structure can, as a whole, surround the entire photo-sensing circuit region, or include a plurality of light-absorbing elements each surrounding one or more photo-sensing devices of the photo-sensing circuit region. In some embodiments, a light absorption coefficient of the light-absorbing structure can be larger than a light absorption coefficient of the semiconductor wafer, such that the light-absorbing structure can absorb at least a portion of the stray light incident on the light-absorbing structure, thereby blocking the at least a portion of the stray light from reaching the photo-sensing circuit region. A material with suitable physical and/or chemical properties (e.g., having a higher light absorption capability than the semiconductor wafer) can be used to form the light-absorbing structure. In some embodiments, the light-absorbing structure may have a darker color than the semiconductor wafer. For example, the light-absorbing structure can have a black color.

In some embodiments, the light-absorbing structure can include a plurality of layers. The plurality of layers may be made of a same material or different materials. The stray light absorbed by the light-absorbing structure can generate heat. Thus, to enhance the heat dissipation capability of the light-absorbing structure (and hence the heat dissipation capability of the image sensor), the light-absorbing structure may have good heat dissipation capability and a higher light absorption capability than the semiconductor wafer. For example, the light-absorbing structure may be made of a material with both a good heat dissipation capability and a light absorption capability higher than that of the semiconductor wafer. For another example, the light-absorbing structure may be made of one or more materials with a good heat dissipation capability and one or materials with a light absorption capability higher than that of the semiconductor wafer. For the light-absorbing structure including a plurality of layers, one or more layers of the plurality of layers may have good heat dissipation capability, and the other layers of the plurality of layers may have a light absorption capability higher than that of the semiconductor wafer.

By using the method of fabricating the image sensor consistent with the present disclosure, the light-blocking structure can be introduced into the image sensor and disposed between the peripheral circuit region and the one or more of the plurality of photo-sensing devices. Through the light-blocking structure, part of or all of the stray light can be prevented from travelling from the peripheral circuit region into the photo-sensing circuit region. As such, the interference signal (e.g., noise) caused by the stray light can be reduced, and hence the signal-to-noise ratio of the image sensor and the maximum amplification applied to the output signal can both be increased. Therefore, the quality of the image acquired by the image sensor can be improved.

In addition, compared to the existing technologies, the light-blocking structure can have a much smaller cross-sectional width than a dummy region used in the existing technologies. As such, the image sensor fabricated using the method consistent with the present disclosure can have a relative higher ratio of effective area (the area of the peripheral circuit region and the photo-sensing circuit region) versus the total area of the image sensor. Thus, the image sensor fabricated using the method consistent with the present disclosure can be more compact, and the cost of materials for fabricating the image sensor can be lowered.

A method of fabricating an image sensor consistent with the disclosure can be automated by semiconductor fabrication equipment controlled by computer program(s) stored in one or more non-transitory computer-readable storage media, which can be sold or used as a standalone product. The computer program(s) can include instructions that enable a computer device, such as a personal computer, a server, or a network device, to control the semiconductor fabrication equipment to perform part or all of a method consistent with the disclosure, such as one of the example methods described above. The storage medium can be any medium that can store program codes, for example, a USB disk, a mobile hard disk, a read-only memory (ROM), a random-access memory (RAM), a magnetic disk, or an optical disk.

Other embodiments of the disclosure will be apparent to those skilled in the art from consideration of the specification and practice of the embodiments disclosed herein. It is intended that the specification and embodiments be considered as examples only and not to limit the scope of the disclosure. Any modification and equivalently replacement for the technical solution of the present disclosure should all fall in the spirit and scope of the technical solution of the present disclosure.

What is claimed is:

1. An image sensor comprising:
a photo-sensing circuit region formed in a semiconductor wafer and including a plurality of photo-sensing devices;
a peripheral circuit region formed in the semiconductor wafer; and
a light-blocking structure between one or more of the photo-sensing devices and the peripheral circuit region, the light-blocking structure:
being configured to block at least a portion of stray light from reaching the one or more of the photo-sensing devices, the stray light coming from the peripheral circuit region; and
including a material different from a material of the semiconductor wafer.

2. The image sensor according to claim 1, wherein the light-blocking structure includes a plurality of light-blocking elements.

3. The image sensor according to claim 2, wherein the plurality of light-blocking elements are arranged in parallel.

4. The image sensor according to claim 1, wherein the light-blocking structure surrounds the photo-sensing circuit region.

5. The image sensor according to claim 1, wherein the light-blocking structure includes a plurality of light-blocking sub-structures each surrounding one or more of the plurality of photo-sensing devices.

6. The image sensor according to claim 1, wherein:
the light-blocking structure includes a light-reflecting structure; and
a refractive index of the light-reflecting structure is lower than a refractive index of the peripheral circuit region.

7. The image sensor according to claim 6, wherein the light-blocking structure has a trapezoidal shape.

8. The image sensor according to claim 6, wherein the light-reflecting structure includes at least one of silicon dioxide, silicon nitride, tungsten, hafnium oxide, or carbon.

9. The image sensor according to claim 6, wherein the light-reflecting structure includes a plurality of layers.

10. The image sensor according to claim 1, wherein the light-blocking structure includes a light-absorbing structure.

11. The image sensor according to claim 10, wherein a light absorption coefficient of the light-absorbing structure is larger than a light absorption coefficient of the semiconductor wafer.

12. The image sensor according to claim 10, wherein the light-absorbing structure has a darker color than the semiconductor wafer.

13. The image sensor according to claim 12, wherein the light-absorbing structure has a black color.

14. The image sensor according to claim 10, wherein the light-absorbing structure includes a plurality of layers.

15. The image sensor according to claim 1,
wherein the photo-sensing circuit region, the peripheral circuit region, and the light-blocking structure are in a device layer of the image sensor;
the image sensor further comprising:
an interconnect wire layer at a first side of the device layer; and
a color-filter layer at a second side of the device layer, the second side being opposite to the first side.

16. The image sensor according to claim 1, wherein the stray light is generated in the peripheral circuit region.

17. The image sensor according to claim 1, wherein the stray light passes through the peripheral circuit region.

18. A method of fabricating an image sensor comprising:
forming a device layer in a semiconductor wafer, the device layer including a photo-sensing circuit region and a peripheral circuit region, the photo-sensing circuit region including a plurality of photo-sensing devices; and
forming a light-blocking structure in the semiconductor wafer between one or more of the photo-sensing devices and the peripheral circuit region, the light-blocking structure:
being configured to block at least a portion of stray light from reaching the one or more of the photo-sensing devices, the stray light coming from the peripheral circuit region; and
including a first material different from a second material of the semiconductor wafer.

19. The method according to claim 18, wherein forming the light-blocking structure includes forming the light-blocking structure surrounding the photo-sensing circuit region.

20. The method according to claim 18, wherein forming the light-blocking structure in the semiconductor wafer includes:
etching the semiconductor wafer from the side of the semiconductor wafer to form at least one trench between the one or more of the photo-sensing devices and the peripheral circuit region;
filling the at least one trench with the first material to form the light-blocking structure.
